(19) United States
(12) Patent Application Publication
(10) Pub. No.: US 2025/0364459 A1
(43) Pub. Date: Nov. 27, 2025

(54) ELECTRONIC DIE ASSEMBLY COMPRISING SUPERCONDUCTING INTERCONNECTION PADS

(71) Applicant: COMMISSARIAT A L'ENERGIE ATOMIQUE ET AUX ENERGIES ALTERNATIVES, PARIS (FR)

(72) Inventors: Jean CHARBONNIER, GRENOBLE CEDEX (FR); Candice THOMAS, GRENOBLE CEDEX (FR); Franck FOURNEL, GRENOBLE CEDEX (FR); Pablo RENAUD, GRENOBLE CEDEX (FR); Emilie BOURJOT, GRENOBLE CEDEX (FR); Nicolas BRESSON, GRENOBLE CEDEX (FR)

(21) Appl. No.: 19/214,530

(22) Filed: May 21, 2025

(30) Foreign Application Priority Data
May 21, 2024 (FR) 2405167

(51) Int. Cl. H01L 23/00

(52) U.S. Cl. CPC H01L 24/06; H01L 24/03; H01L 24/05; H01L 24/08; H01L 24/80; H01L 2224/0347; H01L 2224/05166; H01L 2224/05679; H01L 2224/06177; H01L 2224/08145; H01L 2224/80895; H01L 2924/04941

(57) ABSTRACT

An electronic die assembly includes a first die and a second die superimposed on and electrically and mechanically connected to each other; first superconducting interconnection pads disposed on a first face of the first die and having in a first direction a first repeat pitch less than or equal to 10 μm; and second superconducting interconnection pads disposed on a first face of the second die and having in the first direction a second repeat pitch equal to the first repeat pitch; the first superconducting interconnection pads being in direct contact with the second superconducting interconnection pads; and the first face of the first die and the first face of the second die being separated by a solid matter-free gap.

### CROSS-REFERENCE TO RELATED APPLICATIONS

This application claims priority to French Patent Application No. 2405167, filed May 21, 2024, the entire content of which is incorporated herein by reference in its entirety.

### FIELD

The technical field of the invention is that of three-dimensional electronic die assemblies. The invention more particularly relates to an assembly comprising two electronic dies and superconducting interconnection pads for electrically connecting the two dies while minimising heat transfer between them.

### BACKGROUND

Three-dimensional (3D) integration consists in stacking several electronic dies (also referred to as integrated circuits) and electrically connecting them, for example using a bonding technique. This approach especially makes it possible to reduce overall size of so-called “heterogeneous” systems which are comprised of circuits belonging to different generations of a same semiconductor device technology or circuits belonging to different technologies, for example an image sensor comprising an array of photodiodes and a CMOS image processing circuit comprising logic circuits. 3D integration also makes it possible to increase the density of transistors per unit area without reducing their dimensions, to reduce power consumption and/or to increase the operating speed of a system, by replacing long horizontal interconnections with short vertical interconnections.

There are several 3D stacking architectures, especially as a function of the way the dies are stacked, the orientation of the dies and the type of bonding.

Stacking can be made according to different approaches: wafer-to-wafer, die-to-wafer or even die-to-die. The wafer-to-wafer technique is the fastest in terms of the number of dies bonded per hour, because it is collective bonding on the scale of silicon wafers. It is also the most accurate for a given bonding speed. On the other hand, unlike the other two techniques, does not offer the option of assembling only so-called “Known Good Dies”, selected after a series of tests and cutting of the wafers. The die-to-die stacking technique naturally takes the longest to implement, as the dies are bonded together two by two after the wafers have been cut.

When the dies (or wafers) are oriented in the same sense, the front face of one die is bonded to the back face of another die (this assembly method is referred to as “face-to-back”). Conversely, when the dies (or wafers) are assembled after one of them has been turned over, the dies are bonded face-to-face or back-to-back.

Paper [“Hybrid bonding for 3D stacked image sensors: impact of pitch shrinkage on interconnect robustness”; J. Jourdon et al., 2018 IEEE International Electron Devices Meeting (IEDM), pp. 7.3.1-7.1.4, 2018] describes an example of a 3D stack comprising two electronic dies assembled face-to-face by hybrid bonding (Cu/SiO₂). The upper die is a BackSide Illuminated (BSI) image sensor and the lower die is an image processing logic circuit manufactured using CMOS technology. The two dies are assembled using copper interconnection pads surrounded by silicon dioxide. The interconnection pads (also referred to as HBM (Hybrid Metal Bonding) pads) have a repeat pitch between 1.44 μm and 8.8 μm.

In some applications, interconnections are designed to limit heat transfer between the electronic dies they connect as much as possible. Typically, when a first die is intended to operate at a very low temperature, it is necessary to limit heat transfer as much as possible between this first die and a second die that dissipates heat or is subjected to a different temperature, without compromising electrical conduction between the two dies.

By way of example, there can be mentioned quantum computing dies designed to operate at temperatures close to absolute zero (typically below 1.5 K) and to contain quantum bits, commonly referred to as qubits, whose state is highly sensitive to temperature. Such a quantum die is generally disposed in a dilution cryostat and can be electrically coupled to a CMOS technology reading and control circuit, also disposed inside the cryostat. This reading and control circuit, commonly referred to as “cryo-CMOS”, is designed to release as little heat as possible, but should nevertheless be thermally decoupled from the quantum die so as not to impair its operation.

One solution for providing excellent electrical conduction while limiting heat conduction between two dies is to use one or more superconducting materials to make the interconnection between the two dies. Indeed, there are two main mechanisms for heat conduction at low temperatures. Firstly, heat is transferred by free electrons from one material to another. This phenomenon therefore only occurs in electrically conductive materials. On the other hand, heat is also transferred by vibrations of the lattice of atoms, in other words phonons, of the material or materials making up the interconnection. In a superconducting material brought at a temperature below its critical temperature T_{C} (i.e. the superconducting-conducting phase transition temperature), in other words in the superconducting state, free electrons condense into Cooper pairs. These Cooper pairs have the feature of not conducting heat. Using one or more superconducting materials to make the interconnection therefore makes it possible to reduce heat conduction by free electrons. However, when the interconnection temperature is close to the critical temperature T_{C}, residual electrons that have not formed Cooper pairs continue to conduct heat.

For a given superconducting material, the lower the temperature, the more electrons organise themselves into Cooper pairs in the material and therefore the lower the thermal conduction by the residual free electrons. To significantly reduce thermal conduction by free electrons, it is generally considered necessary to reach a temperature T of less than T_{C}/10.

FIGS. 1A and 1B represent an assembly of two electronic circuits 1 and 2, described in patent application FR2984602A1. The electronic circuits 1 and 2 are assembled and electrically connected to each other by means of a network of interconnections 8. Each interconnection 8 comprises two stacks of superconducting thin films 3-4, located at the ends of the interconnection 8. These stacks of thin layers 3-4 form phonon mirrors and therefore limit thermal conduction by the phonons of interconnection 8.

Each interconnection 8 further comprises:
metal layers 5, disposed on the stacks of thin films 3-4 and forming a wetting surface for a solder material; and
a ball-shaped solder pad 6 disposed between the metal layers 5.

This type of interconnection is particularly complex and time-consuming to manufacture. Furthermore, the use of solder balls limits the density of integration, as manufacturing techniques impose ball sizes and inter-ball distances that are very difficult to reduce.

The solder balls are formed of indium, which is also a superconducting material. However, this material has a lower critical temperature T_{C} than the superconducting materials forming the stacks of thin films 3-4, for example niobium (Nb) and titanium nitride (TiN), which means that it has to be operated at an even lower temperature to achieve the “T<T_{C}/10” regime.

Additionally, paper [“Nb—Nb direct bonding at room temperature for superconducting interconnects”, M. Fujino et al, Journal of Applied Physics 133, 015301, 2023] describes the assembly of two silicon substrates by direct bonding of niobium interconnection pads. The interconnection pads, formed on the surface of each of the substrates, have a diameter of 200 μm and a repeat pitch of 650 μm. Such a repeat pitch is especially incompatible with the large-scale integration of quantum dies.

The bonding method used in this paper is Surface Activated Bonding (SAB), which is based on forming metallic bonds between the surfaces to be bonded. The bonding method comprises a so-called surface activation step, carried out under ultra-high vacuum (pressure: 2.10⁻⁶ Pa) and consisting in bombarding the two surfaces to be bonded with argon atoms in order to create dangling bonds, and then a step of bringing the surfaces into contact, still under ultra-high vacuum, with a compression force of 1000 N applied for 30 s.

This bonding method is very restrictive and creates an argon-rich interface layer (as SAB involves argon implantation to a thickness of 4-5 nm from the surface). This argon-rich interface layer can degrade superconducting properties of the interconnection, such as critical temperature (T_{C}), critical current density (J_{C}) and critical field (B_{C}).

### SUMMARY

There is therefore a need to provide an electronic die assembly that is simple to make, and in which the interconnections between dies have good superconducting properties and high density.

According to a first aspect of the invention, this need tends to be met by providing an electronic die assembly comprising:
a first die and a second die superimposed on and electrically and mechanically connected to each other, each of the first and second dies comprising a first face and a second face opposite to the first face, the first face of the first die being disposed facing the first face of the second die;
a plurality of first superconducting interconnection pads disposed on the first face of the first die and having in a first direction a first repeat pitch of less than or equal to 10 μm; and
a plurality of second superconducting interconnection pads disposed on the first face of the second die and having in the first direction a second repeat pitch equal to the first repeat pitch.

Furthermore, in this assembly, the first superconducting interconnection pads are in direct contact with the second superconducting interconnection pads, and the first face of the first die and the first face of the second die are separated by a solid matter-free gap.

The material-free, especially dielectric material-free, inter-die gap reduces heat conduction between dies (as well as the use of superconducting interconnect pads), crosstalk and dielectric losses. The direct contact between the first superconducting interconnection pads and the second superconducting interconnection pads provides good superconducting properties to the interconnections between dies. These properties, combined with the high interconnection density provided by the repeat pitch, enable the die assembly to meet the requirements of many applications in fields of quantum computing, superconducting electronics and space.

In an embodiment, the first superconducting interconnection pads are bonded to the second superconducting interconnection pads by hydrophilic direct bonding.

In a first embodiment of the assembly, the first superconducting interconnection pads and/or the second superconducting interconnection pads consist of one and the same superconducting material.

The first superconducting interconnection pads and/or the second superconducting interconnection pads may each comprise a stack of at least one first superconducting layer and at least one second superconducting layer, said at least one first superconducting layer being formed of a first superconducting material and said at least one second superconducting layer being formed of a second superconducting material different from the first superconducting material.

In a second embodiment, the first superconducting interconnection pads and/or the second superconducting interconnection pads each comprise a stack a plurality of alternating first superconducting layers and second superconducting layers. The first superconducting layers are formed of a first superconducting material and the second superconducting layers are formed from a second superconducting material different from the first superconducting material.

According to one development, the first superconducting material and the second superconducting material are selected so as to form at least one acoustic mismatch interface.

Further to the characteristics just discussed in the preceding paragraphs, the electronic die assembly according to the first aspect of the invention may have one or more complementary characteristics from among the following, considered individually or according to any technically possible combinations:
the first superconducting interconnection pads have a third repeat pitch in a second direction intersecting the first direction and the second superconducting interconnection pads have a fourth repeat pitch in the second direction equal to the third repeat pitch;
the third repeat pitch is less than or equal to 10 μm, for example between 1 μm and 7 μm;
the third repeat pitch is equal to the first repeat pitch;
the first die is a quantum circuit and the second die is a circuit for reading and controlling the quantum circuit;
the first die is an infrared bolometric sensor and the second die is a multiplexing circuit or a circuit for reading the infrared bolometric sensor; and
the first repeat step is between 1 μm and 7 μm.

A second aspect of the invention relates to a method for manufacturing an electronic die assembly comprising a first die and a second die superimposed on and electrically and mechanically connected to each other, each of the first and second dies comprising a first face and a second face opposite to the first face. The method comprises the following steps of:
forming a plurality of first superconducting interconnection pads on the first face of the first die, the first superconducting interconnection pads having a first repeat pitch of less than or equal to 10 μm in a first direction;
forming a plurality of second superconducting interconnection pads on the first face of the second die, the second superconducting interconnection pads having a second repeat pitch in the first direction equal to the first repeat pitch;
assembling the first die and the second die by hydrophilic direct bonding, by bringing the first superconducting interconnection pads into contact with the second superconducting interconnection pads, so that the first face of the first die and the first face of the second die are disposed facing each other and separated by a solid matter-free gap.

In a mode of implementation, forming the first superconducting interconnect pads comprises the following sub-steps of:
forming a superconducting layer on the first face of the first die;
polishing the superconducting layer so as to achieve a surface roughness of less than 0.5 nm;
forming an etch mask on the superconducting layer;
etching the superconducting layer through the etch mask; and
removing the etch mask.

Beneficially, the manufacturing method further comprises:
prior to forming the superconducting layer, depositing a barrier layer onto the first face of the first die; and
after etching the superconducting layer, etching the barrier layer.

For example, the superconducting layer comprises niobium and the barrier layer is of titanium nitride.

The manufacturing method may further comprise:
between polishing the superconducting layer and forming the etch mask, depositing a protective layer onto the superconducting layer;
prior to etching the superconducting layer, etching the protective layer through the etch mask to expose the superconducting layer; and
after removing the etch mask, removing the protective layer.

Further to the characteristics just discussed in the preceding paragraphs, the manufacturing method according to the second aspect of the invention may have one or more additional characteristics from among the following, considered individually or according to any technically possible combination:
hydrophilic direct bonding is performed at room temperature and under atmospheric pressure;
the hydrophilic direct bond is performed under vacuum, with a residual pressure between 10⁻² Pa and 1000 Pa (104 mbar and 10 mbar); and
the manufacturing method comprises, after the step of assembling the first die and the second die, a step of annealing the assembly at a temperature between 100° C. and 400° C., for example between 100° C. and 350° C., such as between 100° C. and 300° C.

### BRIEF DESCRIPTION OF THE FIGURES

Further characteristics and benefits of the invention will become apparent from the description thereof given below, by way of indicating and in no way limiting purposes, with reference to the appended figures, in which:

FIG. 1A, previously described, represents a die assembly according to prior art;

FIG. 1B, previously described, represents one of the interconnections of the die assembly of FIG. 1A, this interconnection comprising several superconducting layers;

FIG. 2 represents a cross-sectional view of a first embodiment of a die assembly according to the first aspect of the invention;

FIG. 3 represents a cross-sectional view of a second embodiment of a die assembly according to the first aspect of the invention;

FIG. 4 represents the first face of one of the dies of the assembly of FIG. 2 or FIG. 3;

FIGS. 5A-5D, 6A-6D and 7 represent steps of a method for manufacturing electronic die assembly according to the second aspect of the invention.

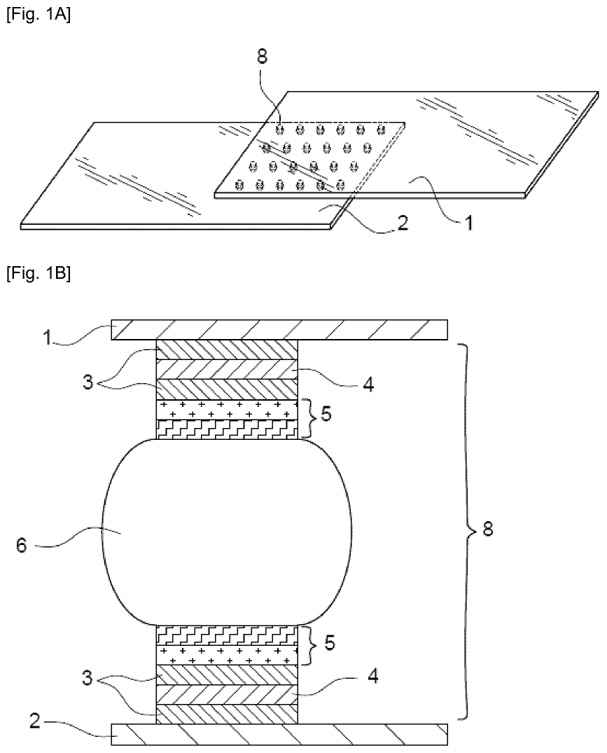

For greater clarity, identical or similar elements are identified by identical reference signs throughout the figures.

### DETAILED DESCRIPTION

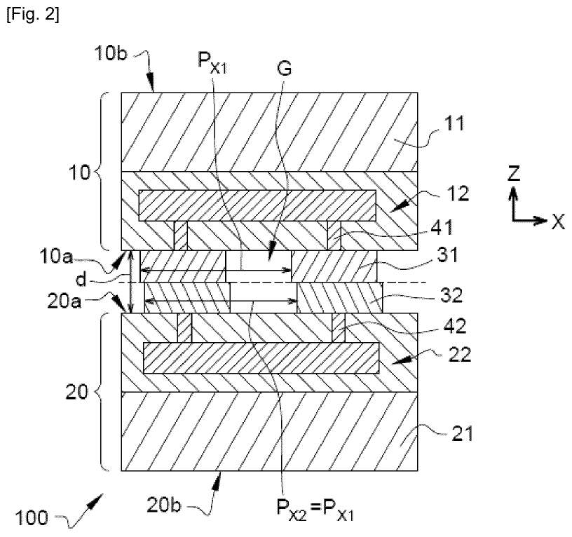

FIG. 2 is a schematic partial cross-section view of an electronic die assembly 100 according to a first embodiment of the invention. The electronic die assembly 100, referred to hereinafter simply as “assembly 100”, comprises at least two electronic dies: a first die 10 and a second die 20. By “electronic die”, it is meant an electronic component based on a semiconductor material, fulfilling one or more electronic functions and integrating several electronic components in a reduced volume. The expression “integrated circuit” will be considered as a synonym for electronic die.

The first die 10 and the second die 20 are superimposed, in other words disposed one on top of the other. As such, assembly 100 can also be designated by the term “die stack”. In the orientation of FIG. 2, the first die 10, referred to as the upper die, is disposed above the second die 20, referred to as the lower die. Furthermore, the first die 10 and the second die 20 are electrically and mechanically connected to each other.

The assembly 100 is designed to operate at very low temperature, i.e. at a temperature less than or equal to 1.5 K, typically at a temperature less than or equal to 100 mK. It is designed to limit heat transfer between dies 10 and 20 in order to avoid, for example, the heat released by one of the dies spreading to the other die and preventing it from operating (at very low temperature) or impairing its performance. Assembly 100 especially finds beneficial applications in the fields of quantum computing, superconducting electronics and space.

By way of example, the first die 10 is a quantum circuit, i.e. a circuit designed to contain quantum bits or qubits, and the second die is a circuit for reading and controlling the quantum circuit, for example in CMOS technology. To be brought to a very low temperature, the assembly 100 can be disposed in a dilution cryostat.

According to another example, the first die 10 is a bolometric image sensor (for example for space observation) and the second die 20 is a circuit for reading the bolometric image sensor or a multiplexing circuit.

The first die 10 may comprise a substrate 11 and one or more interconnection levels, also referred to as routing levels, disposed on the substrate 11. The substrate 11 of the first die 10 comprises an active layer of a semiconductor material, such as silicon. It may contain electronic components or devices (not represented) such as transistors, photodiodes, memory cells, quantum devices, bolometers, etc. These electronic devices are at least in partly formed in the semiconductor active layer. The routing level(s) 12 can connect the electronic devices of the first die 10 electrically to each other.

Likewise, the second die 20 may comprise a substrate 21 and one or more routing levels 22 disposed on the substrate 21. The substrate 21 of the second die 20 may contain electronic devices (transistors, photodiodes, memory cells, quantum devices, etc.), formed at least in part in a semiconductor active layer (the semiconductor material may be different from that of the substrate 11). The routing level(s) 22 can connect the electronic devices of the second die 20 electrically to each other.

The electronic devices on a same die belong to a first functional block (or set of technological levels) referred to as “Front End Of Line” or FEOL, while the routing levels 12, 22 on a same die belong to a second functional block referred to as “Back End Of Line” or BEOL.

Each of the first and second dies 10, 20 comprises a first face 10a, 20a and a second face 10b, 20b opposite to the first face 10a, 20a. The first face 10a of the first die 10 is disposed facing the first face 20a of the second die 20. In an embodiment, the first faces 10a and 20a of the dies are planar surfaces extending in parallel to each other.

In addition to the first and second dies 10, 20, the assembly 100 comprises first superconducting interconnection pads 31 (hereinafter designated “first pads 31”) disposed on the first face 10a of the first die 10 and second superconducting interconnection pads 32 (hereinafter designated “second pads 32”) disposed on the first face 20a of the second die 20.

In an embodiment, the first pads 31 are identical in shape and dimensions (within manufacturing tolerances). The second pads 32 may also have an identical shape and dimensions, which may nevertheless be different from those of the first pads.

In a plane parallel to the first face 10a, 20a, the first and second pads 31-32 may have a rectangular (for example square), round or hexagonal cross-section, etc. Their dimensions in this same plane may be between 100 nm and 7 μm, such as between 1 μm and 5 μm.

Each first pad 31 is electrically connected to one of the routing levels 12 of the first die 10 (for example the one closest to the first pads 31), such as by a first conductive via 41. The first pads 31 are thus electrically connected to the electronic devices of the first die 10. Likewise, each second pad 32 is electrically connected to one of the routing levels 22 of the second die 20 (for example the one closest to the second pads 32), such as by a second conductive via 42. When the first or second die 10, 20 comprises several superimposed routing levels 12, 22, these are also electrically connected to each other by conductive vias. Each routing level 12, 22 comprises one or more conductive tracks, which extend in a plane parallel to the first face 10a, 20a of the die in question. The conductive vias extend in a direction perpendicular to this plane. The conductive tracks and conductive vias are lined with a dielectric material.

The conductive tracks and conductive vias beneficially consist of one or more superconducting materials, in order to limit thermal transport inside the dies.

The first pads 31 are in direct contact with the second pads 32. These first and second pads 31-32 provide electrical and mechanical connection between the two dies.

More precisely, each of the first pads 31 is in direct contact with a second pad 32, and conversely, each of the second pads 32 is in direct contact with a first pad 31. In other words, the first and second pads 31-32 are all connected in pairs.

The dies 10 and 20 are interconnected to each other by means of the first and second pads 31-32 by a direct bonding technique, i.e. without introducing any intermediate compound (such as an adhesive, a wax or a low-melting alloy) at the bonding interface, and more particularly by hydrophilic direct bonding. In this way, interconnections between dies 10 and 20 are free of intermediate compounds, especially of solder material. Each interconnection may consist up of a first pad 31 and a second pad 32. The interconnection is therefore entirely superconducting.

In the assembly 100, a gap G separates the first face 10a of the first die 10 and the first face 20a of the second die 20. This gap G also separates the pairs of first and second pads 31-32 from each other. This gap G is free of solid matter, especially dielectric material. It may contain a gas or a mixture of gases, for example air.

Gap G constitutes an inter-die cavity into which the first pads 31 and the second pads 32 extend. This inter-die cavity is in an embodiment open onto the external environment. Thus, when using assembly 100, for example in a dilution cryostat, the pressure of the gas or gas mixture in gap G can be reduced until a given vacuum level is achieved.

The material-free gap G improves thermal insulation between dies 10 and 20 (by limiting the thermal transport of phonons between the dies), compared to two dies separated by an underfill material or by an oxide (as in the case of Cu/SiO₂ hybrid bonding, for example). Furthermore, gap G limits crosstalk between RF signals propagating in the two dies. By “RF signals”, it is meant signals with a frequency between 3 kHz and 300 GHz. As gap G further separates the first pads 31 from each other and the second pads 32 from each other, it also limits crosstalk between RF signals propagating in different interconnections. Finally, because there is no dielectric material between the interconnection pads, dielectric losses are also reduced.

The distance d between the first face 10a of the first die 10 and the first face 20a of the second die 20 (in other words the height of the inter-die cavity) is beneficially between 100 nm and 2 μm. It is measured perpendicularly to the first faces 10a and 20a.

The first pads 31 have, in a first direction X of the plane of the first face 10a, a first repeat pitch P_{X1} less than or equal to 10 μm, such as between 1 μm and 7 μm. Furthermore, the second pads 32 have, in the same direction X, a second repeat pitch P_{X2} equal to the first repeat pitch P_{X1}.

Such repeat pitches ensure excellent mechanical strength between dies 10 and 20 and enable a high density of interconnections between the dies, compatible with some high integration density applications. These repeat pitches are especially compatible with the need to scale up quantum circuits. Indeed, quantum circuits are designed to contain a very large number of qubits, which have to be connected individually to the reading and control circuit. The number of interconnections required between dies is therefore very high, in particular in quantum circuits with spin qubits in silicon.

The use of superconducting interconnection pads decreases thermal conduction by electrons between dies 10 and 20 (when used at very low temperatures). Fully superconducting interconnects are furthermore of particular interest when the first die 10 is a quantum circuit with superconducting qubits, as they enable phase and amplitude properties of the signal to be retained when moving from one die to another.

The first and second pads 31-32 consist of one or more superconducting materials, for example selected from niobium (Nb), niobium-titanium (NbTi), niobium-germanium (Nb₃Ge), niobium nitride (NbN), niobium alumina (Nb₃Al), tantalum (Ta), tantalum nitride (TaN), titanium nitride (TiN), vanadium (V) and vanadium silicide (V₃Si). The first pads 31 and/or the second pads 31-32 may be formed of an alloy of at least two of these materials. They may also comprise several stacked superconducting layers of different materials.

In this first embodiment, the first pads 31 consist of one and the same superconducting material (for example selected from the aforementioned materials and their alloys). Likewise, the second pads 32 consist of one and the same superconducting material, which may be the same as or different from that of the first pads 31. The first and second pads 31-32 are for example of niobium.

In one alternative embodiment not represented in the figures, the first pads 31 and/or the second pads 32 each comprise a stack of a first superconducting layer and a second superconducting layer. The first superconducting layer is formed of a first superconducting material, for example TiN, and the second superconducting layer is formed of a second superconducting material different from the first superconducting material, for example niobium. The first superconducting layer is the one in contact with the die 10, 20. Thus when the first and second pads 31-32 all comprise stacks, bonding takes place between the second superconducting layers.

The first superconducting material and the second superconducting material can be selected to form an acoustic mismatch interface (also referred to as a Kapitza interface). Such an interface allows part of the phonons to be reflected and therefore decreases thermal conductivity of the interconnections by phonons. Indeed, an interface thermal resistance is created at the interface between the first and second superconducting layers. The greater the difference in the sound velocity between the two superconducting materials the greater this interface thermal resistance. This velocity difference results in a very effective reflection of phonons at the interface, which is why the term “phonon mirror” is also employed.

Examples of superconducting material pairs to create an acoustic mismatch interface are described in patent applications FR3125359A1 and FR2984602A1.

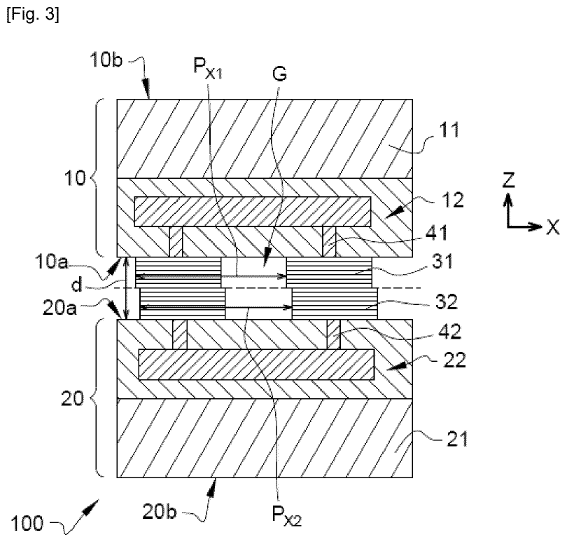

FIG. 3 represents, in the same partial cross-section view, a second embodiment of assembly 100, which differs from the first embodiment only in the composition of the first and second pads 31-32.

Herein, the first pads 31 and the second pads 32 each comprise a stack of alternating several first superconducting layers and several second superconducting layers, in order to form a multitude of acoustic mismatch interfaces (for example more than 10 interfaces) and thus drastically reduce thermal conduction by phonons between the two dies. The greater the number of interfaces, the more effective the phonon mirror.

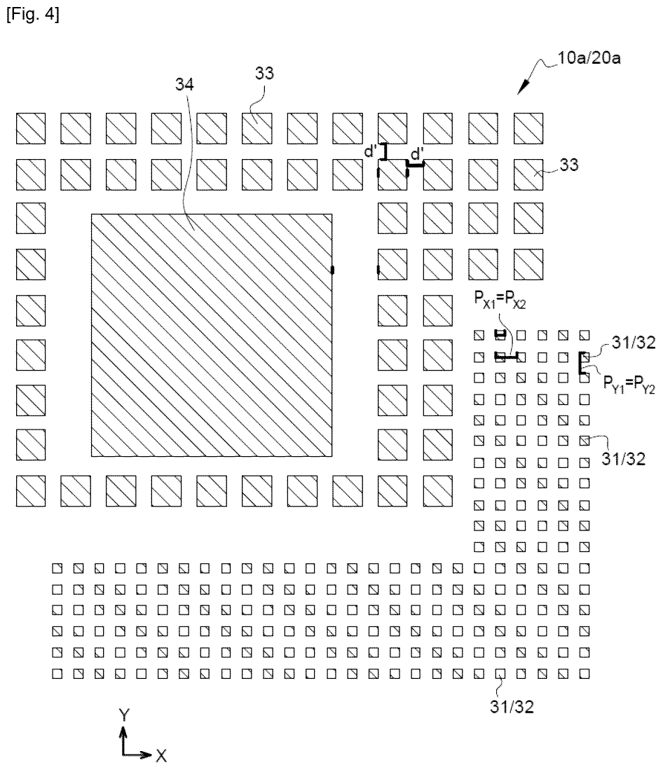

FIG. 4 represents an example of layout of the first pads 31 on the first face 10a of the first die 10 or of the second pads 32 on the first face 20a of the second die 20. The first and second pads 31-32 herein have a square cross-section.

As is represented, the first pads 31 may have a third repeat pitch P_{Y1} in a second direction Y intersecting the first direction X, and the second pads 32 may have a fourth repeat pitch P_{Y2} in the second direction Y equal to the third repeat pitch P_{Y1}. In this way, the first and second pads 31-32 are arranged in a regular array, or matrix, comprising rows and columns. The second direction Y is in an embodiment perpendicular to the first direction X. The third repeat pitch P_{Y1} is beneficially less than or equal to 10 μm, such as between 1 μm and 7 μm. It may be equal to the first repeat pitch P_{X1}. The first or second pads 31, 32 then form a square mesh network.

The first and second pads 31-32 are functional pads in that they are connected to the electronic devices on the dies 10, 20 by the routing levels 12, 22. Beneficially, they are contained in a so-called active zone on the first face 10a, 20a.

In addition to these functional pads, assembly 100 may comprise, on the first face 10a, 20a of each of the dies 10, 20, other pads, especially non-functional bonding pads 33, also referred to as “dummies”. These non-functional pads 33 are used exclusively for bonding two dies together. In other words, they are mechanical only (and not electrical) connection pads. They are connected to neither electronic devices on dies 10, 20, nor routing levels 12, 22.

The non-functional pads 33 are beneficially placed to avoid having large pad-free zones, typically greater than 100×100 μm², beneficially greater than 20×20 μm². For example, they have the shape of squares with sides of 2 μm to 100 μm and are spaced two by two by a distance d′ between 2 μm and 50 μm.

Finally, the assembly 100 may comprise, on the first face 10a, 20a of each of the dies 10, 20, one or more test pads 34 enabling the correct operation of the dies to be verified before they are bonded. These test pads 34 participate in bonding in the same way as the first and second pads 31-32 and the non-functional pads 33. These test pads 34 are typically much larger than the functional pads 31-32 and the non-functional pads 33.

The non-functional pads 33 and the test pads 34 of each die are beneficially formed of the same superconducting material or materials as the first or second pads 31, 32. This helps to reduce heat conduction between the two dies.

The (bonding) surface area of the bonding pads, all types combined (first/second pads, non-functional pads and test pads), is in an embodiment greater than 30% of the surface area of the first face 10a, 20a, such as greater than 45%.

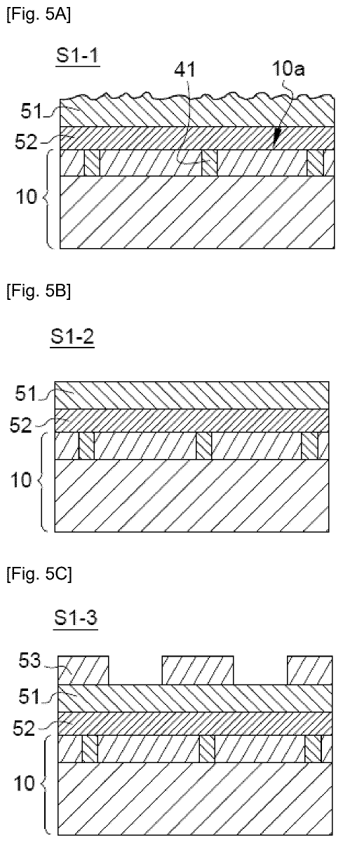

FIGS. 5A to 5D, 6A to 6D and 7 schematically represent steps S1 to S3 of a method for manufacturing the die assembly 100.

The manufacturing method comprises a step S1 of forming first pads 31 on the first face 10a of the first die 10 and a step S2 of forming second pads 32 on the first face 20a of the second die 20.

According to a mode of implementation, step S1 of forming the first pads 31 comprises several sub-steps S1-1 to S1-4 represented by FIGS. 5A to 5D.

Sub-step S1-1 of FIG. 5A comprises forming a superconducting layer 51 on the first face 10 of the first die 10. The thickness of the superconducting layer 51 may be between 100 nm and 10 μm, for example 400 nm.

The superconducting layer 51 may comprise several sub-layers formed of different superconducting materials, especially to form one or more acoustic mismatch interfaces, as previously indicated.

The manufacturing method may also include depositing a barrier layer 52 prior to forming the superconducting layer 51. The barrier layer 52 enables the superconducting layer 51 to better adhere to the first face 10a of the first die 10 and to protect the superconducting layer 51 from oxidation, by forming a barrier to the diffusion of oxidising species. It is formed of an electrically conductive, beneficially superconductive, material, such as titanium nitride (TiN). Titanium nitride is particularly appropriate for a superconducting layer 51 comprising niobium (Nb NbTi, Nb₃Ge, NbN, Nb₃Al, etc.). The thickness of the barrier layer 52 can be between 5 nm and 200 nm, for example 20 nm. With such a thickness, the barrier layer 52 becomes superconducting by proximity effect with the superconducting layer 51 even if it were formed of a non-superconducting material.

The superconducting layer 51 is in an embodiment in electrical contact with first conductive vias 41 (which open onto the first face 10a of the first die 10), via the barrier layer 52 if necessary, in order to connect the future first pads 31 to an underlying routing level 12 (not represented in FIGS. 5A-5D).

Sub-step S1-2 of FIG. 5B consists in polishing the superconducting layer 51 so as to achieve a surface roughness compatible with hydrophilic direct bonding, typically less than 0.5 nm, such as less than 0.2 nm. These roughness values are expressed as root mean square values. The root mean square roughness (noted Rq) is determined by statistical analysis of an atomic force microscope image, taking a surface area of 1×1 μm² as sample.

This polishing sub-step S1-2 can be carried out by Chemical Mechanical Polishing (CMP).

The superconducting layer 51 polished is then structured to form the first pads 31. This structuring is herein accomplished in two sub-steps S1-3 and S1-4 illustrated by FIGS. 5C and 5D.

In S1-3 (see FIG. 5C), an etch mask 53 is formed on the superconducting layer 51. The etch mask 53 may be a resin mask or a hard mask. Its formation especially includes a photolithography step. The etch mask 53 comprises first patterns (formed by solid parts of the mask) whose shape and dimensions correspond to those of the first pads 31 to be formed. The etch mask 53 may also include other patterns (not represented) corresponding to the other bonding pads on the dies (non-functional pads 33 and test pads 34).

And then, in sub-step S1-4 (see FIG. 5D), the superconducting layer 51 is etched through the etch mask 53, thus obtaining the first pads 31 (and, if necessary, the non-functional pads 33 and test pads 34). The superconducting layer 51 is in an embodiment etched by Reactive Ion Etching (RIE).

The barrier layer 52 is also etched through the etch mask 53 in the sub-step S1-4, so as not to short-circuit the first pads 31. Etching of the barrier layer 52 can be performed immediately after etching of the superconducting layer 51 and in the same etching frame, such as using the same chemistry.

Finally, the etch mask 53 is removed after etching sub-step S1-4.

Beneificially, the manufacturing method further comprises, between polishing the superconducting layer 51 (sub-step S1-2) and forming the etch mask 53 (sub-step S1-3), depositing a protective layer onto the superconducting layer 51. This protective layer, also referred to as an encapsulation layer, protects the superconducting layer 51 from forming the etch mask 53, etching the superconducting layer 51 and removing the etch mask 53 so that the first pads 31 have an upper face without impairments (e.g. oxidation), defects or residues. The protective layer is, for example, of silicon dioxide (SiO₂), silicon nitride (SiN) or titanium (Ti). Its thickness is in an embodiment between 5 nm and 2 μm in the case of SiO₂ or SiN and between 5 nm and 500 nm in the case of titanium.

Between forming the etch mask 53 (sub-step S1-3) and etching the superconducting layer 51 (sub-step S1-4), the protective layer is etched through the etch mask 53 to expose the superconducting layer 51 (so-called protective layer opening sub-step). The protective layer is removed after removing the etch mask 53, such as by wet etching, for example in a dilute hydrofluoric acid (HF) solution.

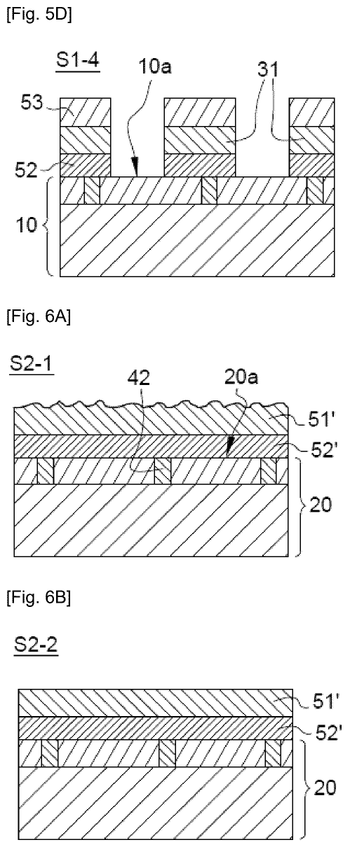

Forming the second pads 32 on the first face 20a of the second die 20 can be carried out in the same way as forming the first pads 31. Thus, the above description of step S1 applies mutatis mutandis to step S2, which especially comprises the sub-steps S2-1, S2-2, S2-3 and S2-4 illustrated in FIG. 6A, FIG. 6B, FIG. 6C and FIG. 6D respectively. Thus, beneficially a second barrier layer 52′, a second superconducting layer 51′, beneficially a second protective layer and a second hard mask 53′ will be formed.

At the end of steps S1 and S2, the first pads 31 project from the first face 10a of the first die 10, and the second pads 32 project from the first face 20a of the second die 20. They are herein raised by portions of the barrier layer 52, 52′.

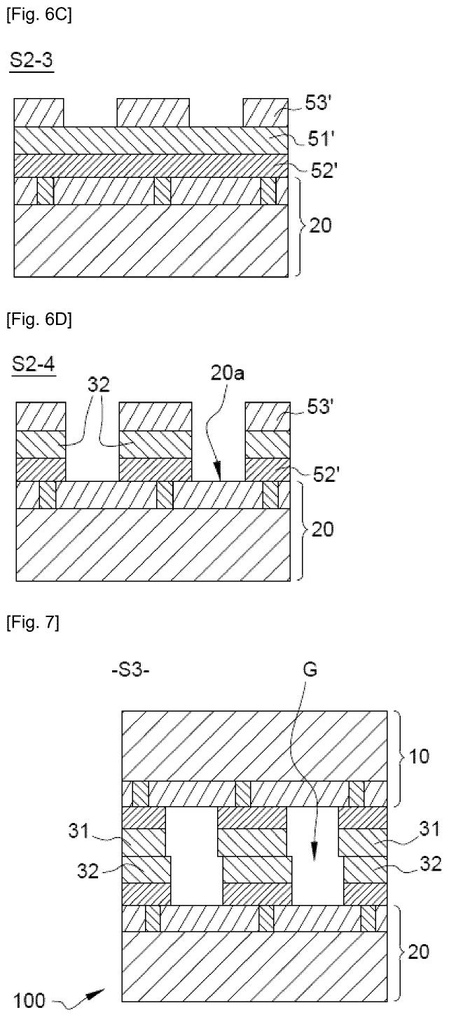

Step S3 in FIG. 7 consists in assembling the first and second dies 10, 20 by hydrophilic direct bonding, by bringing the first pads 31 into contact with the second pads 32, resulting in the assembly 100.

Hydrophilic direct bonding, or hydrophilic molecular adhesion bonding, is a bonding technique that implements hydrophilic bonding surfaces (which is the case of the upper faces of the first and second pads 31-32) and whose principle is based on the spontaneous adhesion of surfaces by virtue of van der Waals forces (including hydrogen bonds and capillary bridges). It can be carried out at room temperature and under atmospheric pressure, unlike surface activated bonding (SAB) which is made under ultra-high vacuum. Aligning the first pads 31 with the second pads 32 is also easier than with SAB. It can be made in a hybrid bonding machine conventionally used for 3D applications. Additionally, there is no need to apply a compression force between the two dies, as this type of bonding is spontaneous. For all these reasons, hydrophilic direct bonding is particularly simple and quick to implement. It is furthermore compatible with the methods used in the microelectronics industry.

Additionally, hydrophilic direct bonding brings about very few defects at the bond interface, such as voids. Furthermore, it does not produce an interface layer with, for example, implanted argon atoms, which can originate degradation of the superconducting properties of the interconnection, such as the critical temperature (T_{C}), the critical current density (J_{C}) and the critical field (B_{C}).

However, hydrophilic direct bonding can optionally be made under vacuum, with a vacuum level between 10⁻² Pa and 1000 Pa (10⁻⁴ mbar and 10 mbar), which is much easier and more economical to achieve than ultra-high vacuum (10⁻⁶-10⁻¹⁰ Pa, corresponding to 10⁻⁸-10⁻¹² mbar). It can also be made in an atmosphere containing helium, or even a humid atmosphere containing helium, with a humidity level of up to 80%.

After bonding, the manufacturing method can also include a step of annealing the assembly 100 at low temperature, in order to further create metallic bonds between the superconducting pads and thus enhance hold between the dies. The annealing temperature is low enough not to be detrimental to the electronic devices on the dies. It can be between 100° C. and 400° C., such as between 100° C. and 350° C., and for example between 100° C. and 300° C. This annealing step is optional, as the adhesion strength of the dies bonded by hydrophilic direct bonding is already high.

Also optionally, one of the two substrates 11 and 21 can be thinned by grinding and/or (dry or wet) etching.

Steps S1, S2 and S3 (plus any annealing) of the manufacturing method are beneficially implemented on a wafer scale. As such, the first die belongs to a first wafer and the second die belongs to a second wafer. The die assembly 100 is then individualised by cutting the assembly of both wafers.

The first wafer may comprise several copies of the first die 10 and the second wafer may comprise several copies of the second die 20, in order to obtain several copies of the assembly 100.

Hydrophilic direct bonding between two wafers does not generally require the application of force to the back faces of the wafers. It may, however, be useful to apply pressure after or during the bonding operation in order to contact all the pads. This is useful if one or both of the wafers have significant deflection (typically between 100 μm and 500 μm).

After bonding, the wafer assembly may undergo further manufacturing steps, some involving one or more fluids (gas, liquid or plasma). In order to avoid penetration of the fluid into the gap G between the dies 10 and 20, which could damage the dies, the interconnection pads or adversely affect the bonding quality, a peripheral sealing ring can be formed in the zone between wafers. This sealing ring can comprise two parts, one on the surface of the first wafer and the other on the surface of the second wafer. In an embodiment, the first part of the sealing ring is formed at the same time as the first pads 31 (by etching the first superconducting layer 51, previously fully deposited on the wafer) and the second part of the sealing ring is formed at the same time as the second pads 32 (by etching the second superconducting layer 51′, previously fully deposited on the wafer). The first and second parts of the ring are brought into (direct) contact during the hydrophilic direct bonding step S3.

A peripheral sealing ring can alternatively be provided for each die assembly (forming a half-ring on each die), and not at the wafer assembly, to facilitate degassing during annealing and thus avoid stresses due to pressure.

The peripheral sealing ring can be between 10 μm and 2 mm wide, as a function of the number and nature of the technological steps to be carried out after bonding.

In one alternative implementation, only steps S1 and S2 of the manufacturing method are implemented at wafer scale. The hydrophilic direct bonding step S3 is implemented according to the die-to-wafer or die-to-die approach, in other words after the first die has been cut out and/or the second die has been cut out.

The electronic die assembly and its manufacturing method are not limited to the embodiments described above. The first and second embodiments of the assembly can especially be combined in a third embodiment, wherein the first pads 31 are formed of one and the same superconducting material and wherein the second pads 32 each comprise a stack of superconducting layers, or vice versa.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements, components, compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. An electronic die assembly comprising:
a first die and a second die superimposed on and electrically and mechanically connected to each other, each of the first and second dies comprising a first face and a second face opposite to the first face, the first face of the first die being disposed facing the first face of the second die;
a plurality of first superconducting interconnection pads disposed on the first face of the first die and having in a first direction a first repeat pitch less than or equal to 10 μm; and
a plurality of second superconducting interconnection pads disposed on the first face of the second die and having in the first direction a second repeat pitch equal to the first repeat pitch;
wherein the first superconducting interconnection pads are in direct contact with the second superconducting interconnection pads; and
wherein the first face of the first die and the first face of the second die are separated by a solid matter-free gap.

2. The assembly according to claim 1, wherein the first superconducting interconnection pads are bonded to the second superconducting interconnection pads by hydrophilic direct bonding.

3. The assembly according to claim 1, wherein the first superconducting interconnection pads have a third repeat pitch in a second direction intersecting the first direction and wherein the second superconducting interconnection pads have in the second direction a fourth repeat pitch equal to the third repeat pitch.

4. The assembly according to claim 3, wherein the third repeat pitch is less than or equal to 10 μm.

5. The assembly according to claim 3, wherein the third repeat step is equal to the first repeat step.

6. The assembly according to claim 1, wherein the first superconducting interconnection pads and/or the second superconducting interconnection pads are made of one and the same superconducting material.

7. The assembly according to claim 1, wherein the first superconducting interconnection pads and/or the second superconducting interconnection pads each comprise a stack of at least one first superconducting layer and at least one second superconducting layer, said at least one first superconducting layer being formed of a first superconducting material and said at least one second superconducting layer being formed of a second superconducting material different from the first superconducting material.

8. The assembly according to claim 7, wherein the first superconducting material and the second superconducting material are selected to form at least one acoustic mismatch interface.

9. The assembly according to claim 7, wherein the first superconducting interconnection pads and/or the second superconducting interconnection pads comprise a stack a plurality of alternating first superconducting layers and second superconducting layers.

10. The assembly according to claim 1, wherein the first die is a quantum circuit and the second die is a circuit for reading and controlling the quantum circuit.

11. The assembly according to claim 1, wherein the first die is an infrared bolometric sensor and the second die is a multiplexing circuit or a circuit for reading the infrared bolometric sensor.

12. The assembly according to claim 1, wherein the first repeat pitch is between 1 μm and 7 μm.

13. A method for manufacturing an electronic die assembly comprising a first die and a second die superimposed on and electrically and mechanically connected to each other, each of the first and second dies comprising a first face and a second face opposite to the first face, the method comprising:
forming a plurality of first superconducting interconnection pads on the first face of the first die, the first superconducting interconnection pads having in a first direction a first repeat pitch less than or equal to 10 μm;
forming a plurality of second superconducting interconnection pads on the first face of the second die, the second superconducting interconnection pads having in the first direction a second repeat pitch equal to the first repeat pitch;
assembling the first die and the second die by hydrophilic direct bonding, by bringing the first superconducting interconnection pads into contact with the second superconducting interconnection pads, so that the first face of the first die and the first face of the second die are disposed facing each other and separated by a solid matter-free gap.

14. The method according to claim 13, wherein forming the first superconducting interconnection pads comprises:
forming a superconducting layer on the first face of the first die;
polishing the superconducting layer so as to achieve a surface roughness of less than 0.5 nm;
forming an etch mask on the superconducting layer;
etching the superconducting layer through the etch mask; and
removing the etch mask.

15. The method according to claim 14, further comprising:
prior to forming the superconducting layer, depositing a barrier layer onto the first face of the first die; and
after etching of the superconducting layer, etching the barrier layer.

16. The method according to claim 15, wherein the superconducting layer comprises niobium and the barrier layer is of titanium nitride.

17. The method according to claim 14, further comprising:
between polishing the superconducting layer and forming the etch mask, depositing a protective layer onto the superconducting layer;
prior to etching the superconducting layer, etching the protective layer through the etch mask to expose the superconducting layer; and
after removing the etch mask, removing the protective layer.
